(19) United States
(12) Patent Application Publication
(10) Pub. No.: US 2024/0282890 A1
(43) Pub. Date: Aug. 22, 2024

(54) LIGHT EMITTING ELEMENT AND MANUFACTURING METHOD THEREOF

(71) Applicant: TOYODA GOSEI CO., LTD., Kiyosu-shi (JP)

(72) Inventors: Koichi MIZUTANI, Kiyosu-shi (JP); Hideki OMOYA, Kiyosu-shi (JP); Shinichi MATSUI, Kiyosu-shi (JP); Hiroaki MAKINO, Kiyosu-shi (JP)

(21) Appl. No.: 18/419,993

(22) Filed: Jan. 23, 2024

(30) Foreign Application Priority Data
Feb. 16, 2023 (JP) 2023-022147

(51) Int. Cl. H01L 33/40; H01L 33/32

(52) U.S. Cl. CPC H01L 33/405; H01L 33/32; H01L 2933/0016

(57) ABSTRACT

A light emitting element includes a group III nitride semiconductor with an emission wavelength of 200 nm or more and 280 nm or less, the light emitting element includes: a semiconductor layer in which an n layer, a light emitting layer, and a p layer are provided in this order; and a p-electrode provided on and in contact with the p layer, and the p-electrode includes a contact layer that is provided in contact with the p layer, has a thickness of 0.5 nm or more and 6 nm or less, and contains Ru or Ni/Au, and a reflection layer that is provided in contact with the contact layer, has a thickness of 50 nm or more, and contains Al or an alloy mainly containing Al.

### CROSS-REFERENCE TO RELATED APPLICATION

This application is based on and claims priority under 35 USC 119 from Japanese Patent Application No. 2023-022147 filed on Feb. 16, 2023.

### TECHNICAL FIELD

The present invention relates to a light emitting element and a manufacturing method thereof.

### BACKGROUND ART

In recent years, the use of ultraviolet LEDs made of a group III nitride semiconductor with an emission wavelength of UVC (wavelength of 200 nm to 280 nm) for sterilization and disinfection of water, air, and the like is attracting attention, and research and development toward higher efficiency of ultraviolet LEDs are actively conducted.

JP2022-30948A describes a structure in which a p-electrode in a light emitting element made of a group III nitride semiconductor that emits UVC light includes a Rh layer that is in contact with a p-type semiconductor layer and has a thickness of 10 nm or less, and an Al layer that is in contact with the Rh layer and has a thickness of 20 nm or more. It is described that contact resistance can be reduced and a reflectance can be improved by adopting such a structure. In addition, it is described that the Rh layer and the Al layer are mixed by annealing the p-electrode, and the reflectance is improved as compared with a single Rh layer.

### SUMMARY OF INVENTION

In the conventional art, a material capable of making ohmic contact with p-AlGaN or p-GaN has a low reflectance for light in the ultraviolet region (particularly UVC). Al has a high reflectance with respect to light in the ultraviolet region, but cannot make ohmic contact with p-AlGaN or p-GaN. Therefore, there has been a demand for a p-electrode that has a high ultraviolet reflectance and is capable of ohmic contact.

In addition, in JP2022-30948A, there is a possibility that the p layer and Al come into contact with each other due to diffusion of Al, and the contact resistance may be deteriorated.

The present invention has been made in view of such a background, and an object thereof is to provide a light emitting element having a p-electrode that has a high ultraviolet reflectance and is capable of ohmic contact, and a manufacturing method of the same.

One aspect of the present invention provides

a light emitting element formed of a group III nitride semiconductor with an emission wavelength of 200 nm or more and 280 nm or less, the light emitting element including:

a semiconductor layer formed by an n layer, a light emitting layer, and a p layer being stacked in this order; and

a p-electrode provided on and in contact with the p layer,

in which the p-electrode includes

a contact layer that is provided in contact with the p layer, has a thickness of 0.5 nm or more and 6 nm or less, and is made of Ru or Ni/Au, and

a reflection layer that is provided in contact with the contact layer, has a thickness of 50 nm or more, and is made of Al or an alloy mainly containing Al.

Another aspect of the present invention provides

a manufacturing method of a light emitting element formed of a group III nitride semiconductor with an emission wavelength of 200 nm or more and 280 nm or less, the manufacturing method including:

a semiconductor layer forming process of forming a semiconductor layer by stacking an n layer, a light emitting layer, and a p layer in this order on a substrate surface;

a contact layer forming process of forming a contact layer of Rh, Ru, or Ni/Au with a thickness of 0.5 nm or more and 6 nm or less in contact with the p layer;

a heat treatment process of performing heat treatment to reduce contact resistance to the p layer; and

a p-electrode forming process of forming, in contact with the contact layer, a reflection layer having a thickness of 50 nm or more and being of Al or an alloy mainly containing Al to form a p-electrode in which the contact layer and the reflection layer are stacked.

In the light emitting element, an ohmic contact with the p layer can be enabled by the contact layer, and ultraviolet rays can also be reflected by the reflection layer.

As described above, according to the above aspect, it is possible to provide a light emitting element having a p-electrode that has a high ultraviolet reflectance and is capable of ohmic contact, and a manufacturing method of the same.

### BRIEF DESCRIPTION OF DRAWINGS

FIG. 1 is a diagram showing a configuration of a light emitting element according to an embodiment, and is a cross-sectional view perpendicular to a main surface of a substrate.

FIG. 2 is a diagram showing a plane pattern of an electrode of the light emitting element according to the embodiment.

FIG. 3 is a diagram showing a manufacturing process of the light emitting element according to the embodiment.

FIG. 4 is a diagram showing the manufacturing process of the light emitting element according to the embodiment.

FIG. 5 is a diagram showing the manufacturing process of the light emitting element according to the embodiment.

FIG. 6 is a diagram showing the manufacturing process of the light emitting element according to the embodiment.

FIG. 7 is a diagram showing the manufacturing process of the light emitting element according to the embodiment.

FIG. 8 is a diagram showing the manufacturing process of the light emitting element according to the embodiment.

FIG. 9 is a diagram showing the manufacturing process of the light emitting element according to the embodiment.

FIG. 10 is a diagram showing the manufacturing process of the light emitting element according to the embodiment.

FIG. 11 is a graph showing the reflectance of samples a to e.

FIG. 12 is a graph showing the reflectance of samples f and g.

FIG. 13 is a graph showing the reflectance of samples h and i.

### DETAILED DESCRIPTION OF THE INVENTION

A light emitting element is formed of a group III nitride semiconductor with an emission wavelength of 200 nm or more and 280 nm or less. The light emitting element includes: a semiconductor layer formed by an n layer, a light emitting layer, and a p layer being stacked in this order; and a p-electrode provided on and in contact with the p layer. The p-electrode includes a contact layer that is provided in contact with the player, has a thickness of 0.5 nm or more and 6 nm or less, and is made of Ru or Ni/Au, and a reflection layer that is provided in contact with the contact layer, has a thickness of 50 nm or more, and is made of Al or an alloy mainly containing Al.

In the light emitting element described above, the contact layer is made of Ru, a contact resistivity of the p-electrode is 2×10⁻³ Ω·cm² or less, and a reflectance at the emission wavelength is 55% or more.

In the light emitting element described above, the contact layer is made of Ni/Au, a contact resistivity of the p-electrode is 2×10⁻³ Ω·cm² or less, and a reflectance at the emission wavelength is 40% or more.

In the light emitting element described above, a region where a material for the contact layer and a material for the reflection layer are mixed may not be present at an interface between the contact layer and the reflection layer.

A manufacturing method of a light emitting device is a manufacturing method of a light emitting element formed of a group III nitride semiconductor with an emission wavelength of 200 nm or more and 280 nm or less. The manufacturing method of a light emitting element includes: a semiconductor layer forming process of forming a semiconductor layer by stacking an n layer, a light emitting layer, and a p layer in this order on a substrate surface; a contact layer forming process of forming a contact layer of Rh, Ru, or Ni/Au with a thickness of 0.5 nm or more and 6 nm or less in contact with the p layer; a heat treatment process of performing heat treatment to reduce contact resistance to the p layer; and a p-electrode forming process of forming, in contact with the contact layer, a reflection layer having a thickness of 50 nm or more and being of Al or an alloy mainly containing Al to form a p-electrode in which the contact layer and the reflection layer are stacked.

In the manufacturing method of a light emitting element described above, the contact layer is made of Rh, a contact resistivity of the p-electrode is 2×10⁻² Ω·cm² or less, and a reflectance at the emission wavelength is 70% or more.

The contact layer may be made of Ru, a contact resistivity of the p-electrode may be 2×10⁻³ Ω·cm² or less, and a reflectance at the emission wavelength may be 55% or more.

The contact layer may be made of Ni/Au, a contact resistivity of the p-electrode may be 2×10⁻³ Ω·cm² or less, and a reflectance at the emission wavelength may be 40% or more.

### Embodiment

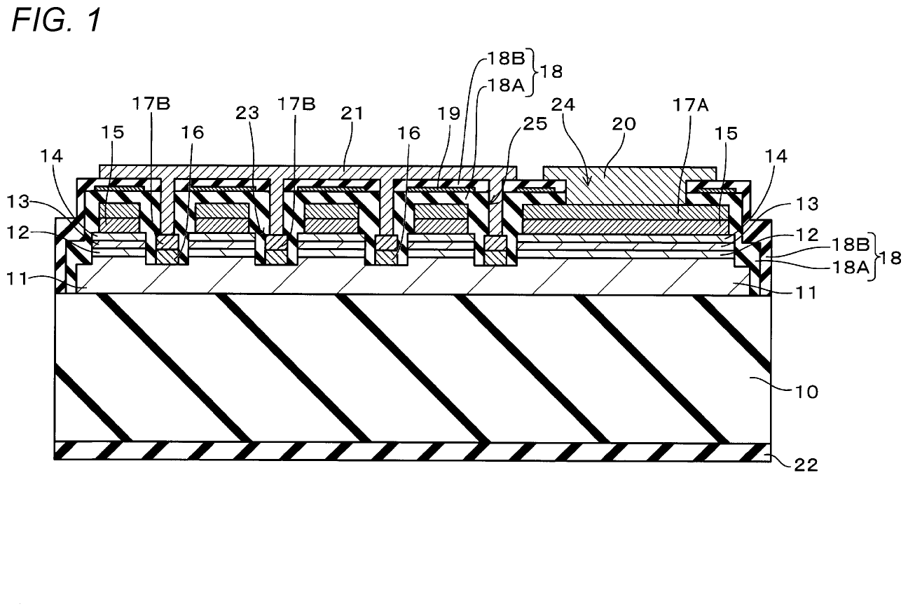

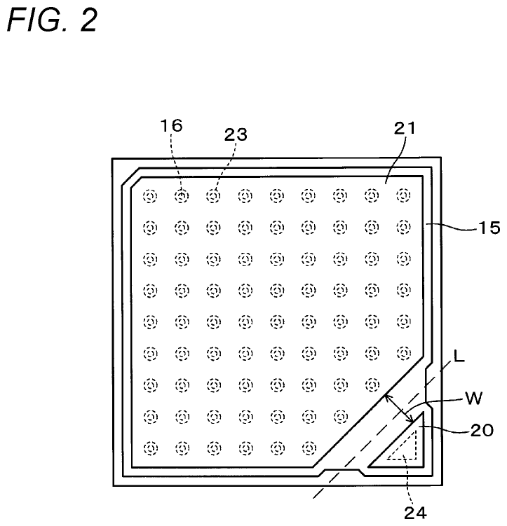

FIG. 1 is a diagram showing a configuration of a light emitting element according to the embodiment, and is a cross-sectional view perpendicular to a substrate. FIG. 2 is a diagram showing a plane pattern of an electrode of the light emitting element according to the embodiment. The light emitting element according to the embodiment is a flip-chip type ultraviolet light emitting element, and has an emission wavelength of UVC, for example, 200 nm to 280 nm.

### 1. CONFIGURATION OF LIGHT EMITTING ELEMENT

As shown in FIG. 1, the light emitting element according to the embodiment includes a substrate 10, an n layer 11, a light emitting layer 12, an electron block layer 13, a p layer 14, a p-electrode 15, n-electrodes 16, pn electrodes 17A and 17B, a protective film 18, a reflection film 19, a p-pad electrode 20, an n-pad electrode 21, and an antireflection film 22. Hereinafter, each configuration will be described.

The substrate 10 is a sapphire substrate having a c-plane as a main surface. Other than sapphire, any material may be used as long as the material has a high transmittance with respect to the emission wavelength and can grow a group III nitride semiconductor. A thickness of the substrate 10 is, for example, 0.4 mm to 1 mm. Within this range, light extraction efficiency can be improved. On the other hand, since the substrate 10 is thick, heat tends to accumulate inside the light emitting element, which reduces heat dissipation performance and shortens the life of the element. In the embodiment, the heat dissipation performance is improved by forming an electrode pattern as described later.

An antireflection film 22 is provided on a back surface (a surface opposite to the n layer 11, a light extraction side) of the substrate 10. By providing the antireflection film 22, it is possible to prevent ultraviolet rays from being reflected on the back surface of the substrate 10 and returning to an element side, thereby improving light extraction.

The antireflection film 22 has a single layer structure or a structure in which materials having different refractive indexes are alternately stacked, and a thickness of each layer is set so that reflections weaken each other due to light interference. The material for the antireflection film 22 is an insulator having transparency with respect to the UVC. For example, SiO₂, HfO₂, MgF₂, or the like is used.

The n layer 11 is located on the substrate 10 via a buffer layer (not shown) interposed therebetween. The n layer 11 is made of n-AlGaN. The n-type impurity is Si, and the Si concentration is 5×10¹⁸/cm³ to 5×10¹⁹/cm³. The n layer 11 may include a plurality of layers.

The light emitting layer 12 is located on the n layer 11. The light emitting layer 12 has an MQW structure in which well layers and barrier layers are alternately and repeatedly stacked. The number of repetitions is, for example, 2 to 5. The well layer is made of AlGaN, and an Al composition thereof is set according to a desired emission wavelength. The barrier layer is made of AlGaN having an Al composition higher than that of the well layer. AlGaInN having a band gap energy larger than that of the well layer may also be used. The light emitting layer 12 may have an SQW structure.

The electron block layer 13 is located on the light emitting layer 12. The electron block layer 13 is made of p-AlGaN having an Al composition ratio higher than that of the barrier layer of the light emitting layer 12. The electron block layer 13 prevents electrons injected from the n-electrode 16 from passing beyond the light emitting layer 12 and diffusing toward the p layer 14.

The p layer 14 is located on the electron block layer 13. The player 14 is made of p-AlGaN. In the light emitting element according to the embodiment, all semiconductor layers from the n layer 11 to the p layer 14 are made of AlGaN, which prevents absorption of ultraviolet rays by the semiconductor layers. The Al composition of the p layer 14 is, for example, 5% to 80%. The p-type impurity is Mg. The Mg concentration is 1×10¹⁹/cm³ or more. The p layer 14 may include a plurality of layers having different Al compositions and Mg concentrations. In this case, a layer in contact with the p-electrode 15 is made of p-AlGaN having an Al composition of 5% to 80%. The p layer 14 is not limited to AlGaN, and may be a group III nitride semiconductor containing Al, and may be AlGaInN.

A hole 23 having a depth reaching the n layer 11 is formed in a region of a surface of the p layer 14. The hole 23 is dot-shaped, and a plurality of the holes 23 are arranged in a lattice pattern (see FIG. 2). The hole 23 is not provided in a region (one corner portion in a rectangular pattern of the element) corresponding to a lower portion of the p-pad electrode 20. The n layer 11 is exposed on a bottom surface of the hole 23. The holes 23 for exposing the n layer 11 are formed in a dot-shaped arrangement pattern, so that reduction in a light emitting area (the area of the p layer 14) due to the holes 23 is reduced as much as possible while the in-plane light emission is ensured, and the light output is improved.

A plane pattern of each hole 23 is, for example, a circle. Alternatively, a polygon such as a regular hexagonal shape may be used. In the case of a regular hexagonal shape, a side surface of the hole 23 is preferably an m-plane. The arrangement pattern of the holes 23 is, for example, a square lattice, a regular triangular lattice, or a honeycomb pattern.

The p-electrode 15 (contact layer) is provided on the p layer 14. The p-electrode 15 is provided on the surface of the p layer 14 except for the vicinity of edges of the p layer 14 (see FIG. 2), thereby ensuring a wide light emitting area. The p-electrode 15 is a reflective electrode that increases the light extraction efficiency by reflecting ultraviolet rays emitted from the light emitting layer 12 toward the substrate 10.

A material for the p-electrode 15 is a material having a low contact with respect to the p layer 14 and having high UVC reflectance, and is Rh, Ru, or Ni/Au. A thickness of the p-electrode 15 is 0.5 nm to 6 nm. For Ni/Au, a thickness of a Ni layer may be one atomic layer or more. By setting such a thickness, it is possible to reduce the contact resistance with the p-electrode 15, and ultraviolet rays can be transmitted and reflected by the Al layer of the pn electrode 17A.

In order to further increase the ultraviolet reflectance while reducing the contact resistance, the thickness of the p-electrode 15 is preferably 1 nm to 4 nm.

A ratio of the area of the p-electrode 15 to an area of an element upper surface (a total area of the holes 23 and the p layer 14) is 70% or more. The plane pattern of the holes 23 and the p-electrode 15 is set to satisfy the above. For example, a diameter, the number of arrays, and an arrangement interval of the holes 23 are adjusted. By increasing the area of the p-electrode 15, it is possible to increase the reflection of the ultraviolet rays by the p-electrode 15 and improve the light extraction efficiency. The ratio is more preferably 75% or more.

The n-electrode 16 is provided on the n layer 11 exposed on the bottom surface of each hole 23. Therefore, the n-electrodes 16 also have a dot-shaped arrangement pattern (see FIG. 2). A material for the n-electrode 16 is a heat-treated V/Al/Ti structure. Other materials such as Ti/Al/Ti can also be used. Specifically, the heat-treated V/Al/Ti structure has a structure in which a layer made of AlNₓ, a layer made of a metal mainly containing Al and containing V and Ti, and a layer made of Ti are stacked in this order.

The layer made of AlNₓ has a thickness of 1 nm to 3 nm. x is, for example, 0.4 to 0.7. Further, x may decrease as a distance from the n layer 11 increases in a thickness direction. In this case, an average of x in the thickness direction is 0.4 to 0.7. Ga may be diffused from the n layer 11 side, and in this case, Al_{y}Ga_{1-y}Nₓ (0.4≤x≤0.7) having an Al composition ratio higher than that of the n layer 11 is used. When the Al composition ratio of the n layer 11 is a, a<y≤1. y is, for example, 0.7 or more. In this case, x may also decrease as the distance from the n layer 11 increases in the thickness direction, and y may increase as the distance from the n layer 11 increases in the thickness direction.

The layer made of a metal mainly containing Al and containing V and Ti has a thickness of 50 nm to 500 nm. The ratio of Al, V, and Ti is, for example, 50 mol % to 85 mol % for Al, 5 mol % to 20 mol % for V, and 10 mol % to 30 mol % for Ti.

In the n-electrode 16 having the above structure, the contact resistance with respect to the n layer 11 is reduced. For example, the contact resistivity of the n-electrode 16 with respect to the n layer 11 is 4×10⁻⁴ Ω·cm² or less. The reason for this is considered to be, firstly, that the layer made of AlNₓ functions as a good contact layer for the n layer 11. Secondly, it is considered that nitrogen vacancies are generated on a surface of the n layer 11, and the contact resistance is reduced because it becomes n-type.

The layer made of Ti is provided as a cover to prevent Al in the n-electrode 16 from evaporating during alloying. TiN, Ni, Pt, Au, or the like may be used, other than Ti.

The pn electrodes 17A and 17B are provided on the p-electrode 15 and the n-electrode 16, respectively. The plane pattern of the pn electrode 17A is the same as the plane pattern of the p-electrode 15. The plane pattern of the pn electrode 17B is the same as the plane pattern of the n-electrode 16, and is a pattern in which a plurality of dots are arranged.

A material for the pn electrodes 17A and 17B is Al/Ti/Ni/Au/Al. An Al layer, which is the first layer of the pn electrodes 17A and 17B, is in contact with the p-electrode 15 and the n-electrode 16, respectively. The Al layer is a reflection layer that reflects ultraviolet rays. The pn electrode 17A is formed after the p-electrode 15 is heat-treated, so that no atomic diffusion occurs between the p-electrode 15 and the Al layer, and an interface between the p-electrode 15 and the Al layer does not include a layer in which the material for the p-electrode and Al are mixed. Therefore, the ultraviolet rays can be reflected by the Al layer without impairing the effect of reducing the contact resistance by the p-electrode 15. That is, it is possible to both reduce a forward voltage Vf and improve the light extraction efficiency.

For example, in the case of Rh/Al, the contact resistivity can be 2×10⁻² Ω·cm² or less and the ultraviolet reflectance in the UVC can be 70% or more. Further, for example, in the case of Ru/Al, the contact resistivity can be 3×10⁻³ Ω·cm² or less and the ultraviolet reflectance in the UVC can be 55% or more. Further, for example, in the case of Ni/Au/Al, the contact resistivity can be 2×10⁻³ Ω·cm² or less and the ultraviolet reflectance in the UVC can be 40% or more.

A thickness of the Al layer in the pn electrodes 17A and 17B is 10 nm to 500 nm. Within this range, the ultraviolet reflectance can be sufficiently increased. The ultraviolet reflectance of the Al layer increases as the thickness of the Al layer increases to about 50 nm, and becomes saturated at 50 nm or more. Therefore, considering the variation in the thickness of the Al layer, the thickness is preferably 80 nm or more. Further, in consideration of reflectance saturation, material cost, film formation time and the like, the thickness is preferably 200 nm or less.

In the embodiment, Al/Ti/Ni/Au/Al is used for the pn electrodes 17A and 17B, but other materials may be used as long as the first layer in contact with the p-electrode 15 is made of Al. Instead of Al, an alloy mainly containing Al may be used.

The protective film 18 is provided to cover the entire element upper surface. That is, the protective film 18 is provided continuously on side surfaces and surfaces of the p-electrode 15, the n-electrode 16, and the pn electrodes 17A and 17B, the surface and a side surface of the semiconductor layer (the n layer 11, the light emitting layer 12, the electron block layer 13, and the p layer 14), a side surface of an element isolation groove 26, and the inside of the holes 23. A material for the protective film 18 is SiO₂ or the like.

The protective film 18 includes two layers, a first protective film 18A and a second protective film 18B, and the reflection film 19 made of Al is provided between the first protective film 18A and the second protective film 18B. The reflection film 19 is entirely provided except for regions where holes 24 and 25, which will be described later, are present. Light is reflected toward the substrate 10 by the reflection film 19 to improve the light extraction efficiency. In addition, by embedding the reflection film 19 in the protective film 18, the heat dissipation performance of the protective film 18 is improved, and migration of the reflection film 19 is prevented.

A material for the reflection film 19 is not limited to Al, and may be any material that has a high reflectance in the emission wavelength. An alloy containing mainly Al may be used. The reflection film 19 may be provided not between the first protective film 18A and the second protective film 18B but in the first protective film 18A or in the second protective film 18B. When a plurality of reflection films 19 are provided, the plane pattern may be changed. The first protective film 18A and the second protective film 18B may be made of the same material or different materials.

The p-pad electrode 20 and the n-pad electrode 21 are spaced apart from each other on the protective film 18. The p-pad electrode 20 is connected to the pn electrode 17A through a hole 24 formed in the protective film 18. The n-pad electrode 21 is connected to each pn electrode 17B via holes 25 formed in the protective film 18. The material for the p-pad electrode 20 and the n-pad electrode 21 is, for example, Ti/Pt/Au/AuSn.

For the plane pattern of the p-pad electrode 20 and the n-pad electrode 21, as shown in FIG. 2, a rectangular pattern slightly inside the rectangular pattern of the element is divided into two by a linear region with a width W along a straight line L forming an angle of 45° with respect to the sides of the rectangle at a corner of the rectangle, one part forming a right isosceles triangle pattern is the p-pad electrode 20, and the other part (a pentagon with the corner of the rectangle cut off) is the n-pad electrode 21. No n-electrode 16 is located under the p-pad electrode 20, and all the n-electrodes 16 are located under the n-pad electrode 21 and connected to the n-pad electrode 21.

The angle of the linear region is not limited to 45°, but is preferably close to 45°, for example, 30° to 60°, and more preferably 40° to 50° in order to reduce the area of the linear region and increase a sum of the areas of the p-pad electrode 20 and the n-pad electrode 21 as much as possible.

The position and width W of the linear region is preferably set such that the sum of the areas of the p-pad electrode 20 and the n-pad electrode 21 is 90% or more with respect to a light emitting area (the area of the p-electrode 15). Of course, the width W is set to such a width that no short circuit occurs between the p-pad electrode 20 and the n-pad electrode 21. For example, the width W is 100 μm or more. Further, the p-pad electrode 20 has a size that allows good bonding to the sub-mount. This is to increase the heat dissipation performance by widening a heat dissipation area (an area of the region of the p-electrode 15 in contact with the sub-mount in plan view).

By setting the plane pattern of the p-pad electrode 20 and the n-pad electrode 21 as described above, the sum of the area of the p-pad electrode 20 and the area of the n-pad electrode 21 can be increased, and the heat dissipation area can be increased, so that the heat dissipation performance of the light emitting element can be increased. In particular, in the UVC light emitting element, although it is necessary to increase the thickness of the substrate 10 to improve light extraction efficiency, the heat dissipation performance is deteriorated. However, since the heat dissipation performance can be improved as described above, sufficient heat dissipation performance can be ensured even when the substrate is made thick.

As described above, in the light emitting element according to the embodiment, Rh, Ru, or Ni/Au with a thickness of 0.5 nm to 6 nm is used as the p-electrode 15, and the Al layer is used as the first layer of the pn electrode 17A, so that the ultraviolet reflectance can be improved while enables the ohmic contact with the p layer 14. As a result, the light emitting element in the embodiment can both reduce the forward voltage Vf and improve the light extraction efficiency.

### 2. MANUFACTURING PROCESS OF LIGHT EMITTING ELEMENT

A manufacturing process of the light emitting element according to the embodiment will be described with reference to the drawings.

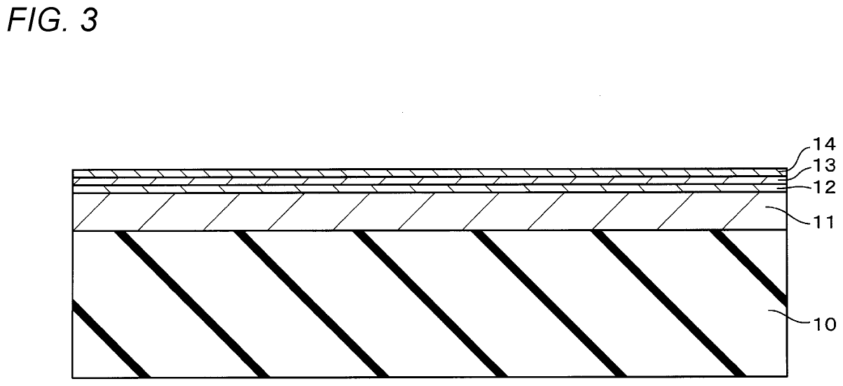

First, the substrate 10 made of sapphire is prepared. Then, the n layer 11, the light emitting layer 12, the electron block layer 13, and the p layer 14 are sequentially formed on the substrate 10 by the MOCVD method (see FIG. 3).

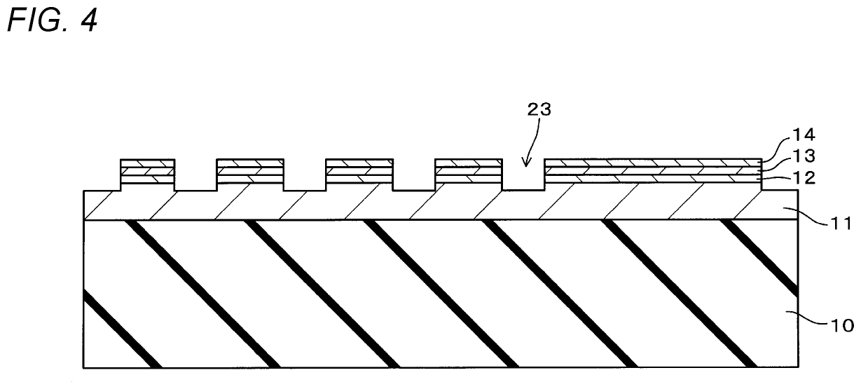

Next, predetermined regions of the p layer 14 is dry etched to form a plurality of holes 23 having a depth reaching the n layer 11 (see FIG. 4).

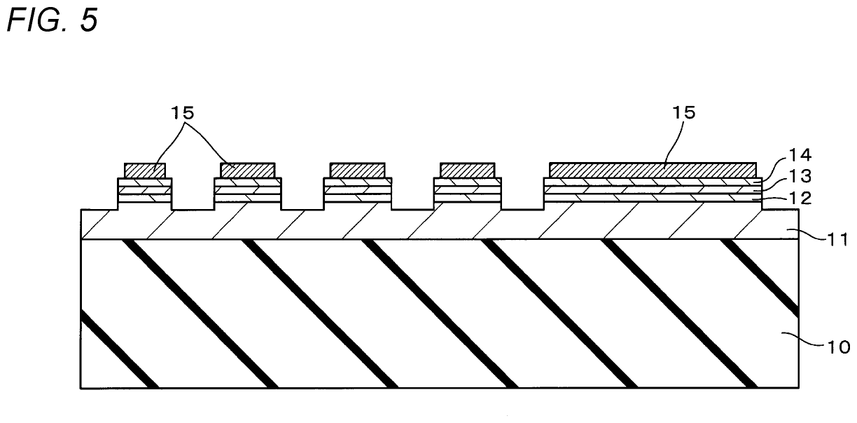

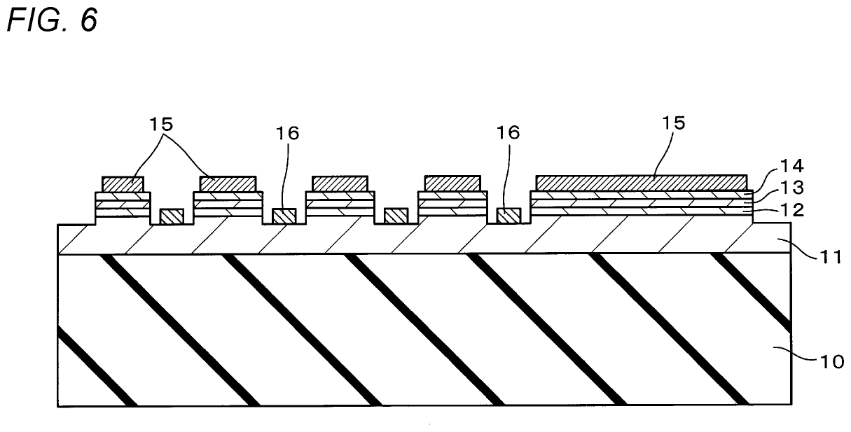

Next, the p-electrode 15 is formed on the p layer 14 by sputtering or vapor deposition (see FIG. 5). Next, a V layer, an Al layer, and a Ti layer are sequentially stacked on the n layer 11 exposed on the bottom surface of the hole 23 by sputtering or vapor deposition to form the n-electrode 16 (see FIG. 6). Although the n-electrode 16 may be formed before the p-electrode 15, in the embodiment, the p-electrode 15 is formed first because it is desired to form the p-electrode 15 with the surface of the p layer 14 as clean as possible.

Next, heat treatment is performed at a temperature of 500° C. to 650° C. for 1 to 10 minutes. The atmosphere is, for example, an inert gas atmosphere such as nitrogen. The heat treatment is preferably carried out under reduced pressure, for example, 1×10² Pa to 1×10⁴ Pa. The heat treatment temperature is preferably 500° ° C. to 600° C. When Ni/Au is used as the p-electrode 15, heat treatment is carried out in an atmosphere containing oxygen.

This heat treatment also serves both to activate Mg in the p layer 14 and to reduce the contact resistance of the p-electrode 15 and n-electrode 16.

In the embodiment, by using V/Al/Ti as the n-electrode 16, the heat treatment temperature is lowered, and the Mg activation treatment of the p layer 14 and the reduction of the contact resistance of the p-electrode 15 and the n-electrode 16 are shared and performed at the same time, thereby reducing the number of heat treatments. As a result of lowering the heat treatment temperature and reducing the number of heat treatments, deterioration of electrical characteristics of the light emitting element can be prevented.

In this regard, the n-electrode 16 changes to the following structure by the heat treatment. Of V/Al/Ti that is the n-electrode 16, V diffuses into Al and does not diffuse into the n layer 11 or Ti. As a result of this diffusion, the V layer disappears. In addition, Al in V/Al/Ti reacts with N in the n layer 11, and AlNₓ is formed at an interface between the n layer 11 and the Al layer. V is considered to act as a catalyst that promotes the reaction between Al and N. As a result of this heat treatment, the structure of the n-electrode 16 changes to a three-layer structure including a layer made of AlNₓ, a layer made of metal mainly containing Al and containing V and Ti, and a layer made of Ti.

By changing the n-electrode 16 to such a structure, the contact resistance of the n-electrode 16 with respect to the n layer 11 is reduced. The reason is as described above. That is, firstly, it is considered that the layer made of AlNₓ functions as a good contact layer with respect to the n layer 11, and secondly, it is considered that the conversion of the n layer 11 into an n-type is further promoted due to the generation of nitrogen vacancies in the n layer 11 from the formation of AlNₓ.

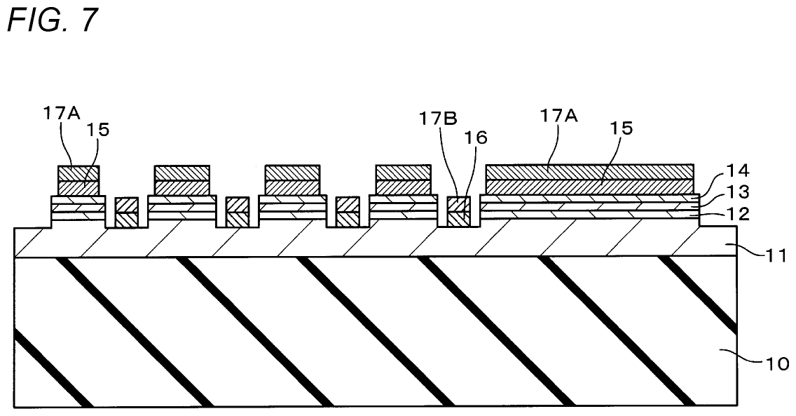

Next, pn electrodes 17A and 17B are formed on the p-electrode 15 and the n-electrode 16 respectively by sputtering or vapor deposition (see FIG. 7). The pn electrodes 17A and 17B are made of Al/Ni/Au/Al, and the Al layer, which is the first layer, is in contact with the p-electrode 15.

In this regard, the pn electrode 17A is formed after the heat treatment of the p-electrode 15, and no heat treatment is performed after the formation of the pn electrode 17A. Therefore, no diffusion of atoms occurs between the p-electrode 15 and the Al layer as the first layer of the pn electrode 17A, and a region where atoms of the p-electrode 15 and Al are mixed is not formed at the interface between the p-electrode 15 and the Al layer. As a result, it is possible to improve the ultraviolet reflectance by the Al layer without impairing good contact of the p-electrode 15 with the p layer 14.

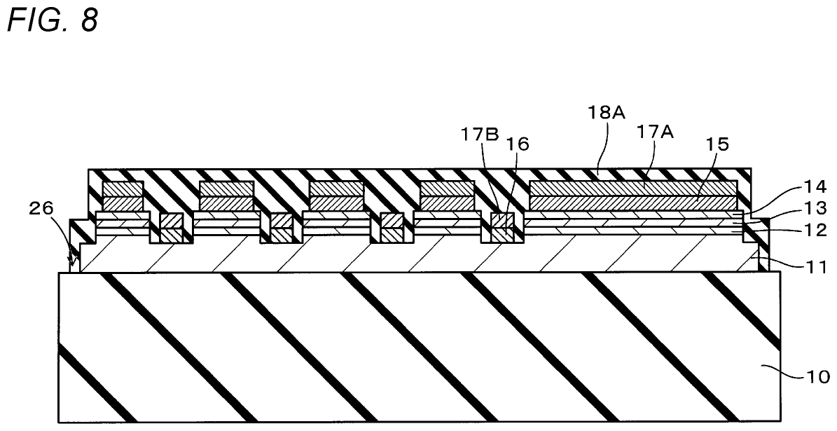

Next, the element isolation groove 26 is formed. The element isolation groove 26 has a depth such that the substrate 10 is exposed. Next, the first protective film 18A covering the entire element upper surface is formed (see FIG. 8). The first protective film 18A is formed by CVD, sputtering, vapor deposition, ALD, or the like. Sputtering, CVD, and ALD are preferred from the viewpoint of film density.

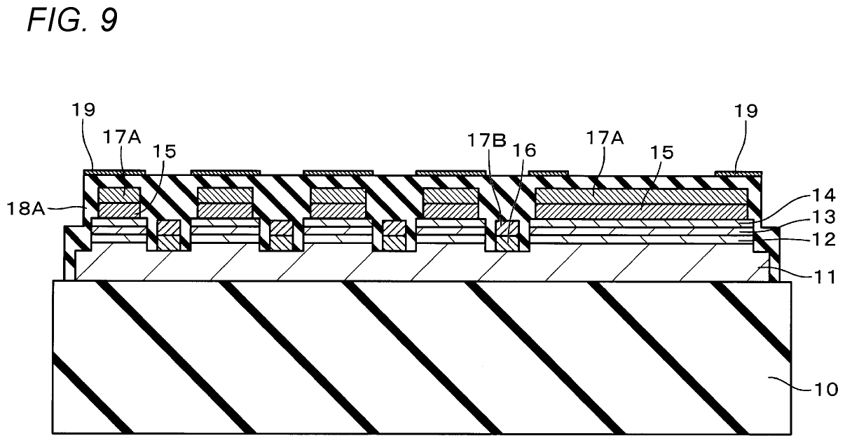

Next, the reflection film 19 made of Al is formed on the first protective film 18A in a region excluding the regions where the holes 24 and 25 are to be formed later (see FIG. 9). The reflection film 19 is formed by vapor deposition or sputtering, and patterned by wet etching.

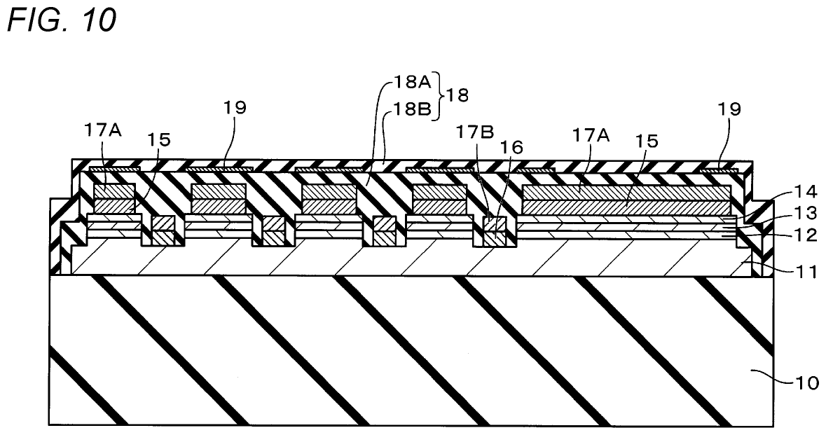

Next, the second protective film 18B is formed on the first protective film 18A and the reflection film 19. The second protective film 18B is formed by CVD, sputtering, vapor deposition, ALD, or the like. Sputtering is preferred from the viewpoint of film density. Thus, the protective film 18 having a structure in which the first protective film 18A and the second protective film 18B are sequentially stacked and the reflection film 19 is formed therebetween is formed (see FIG. 10)

It is preferable that the protective film 18 is not formed on the bottom surface of the element isolation groove 26 and the protective film 18 is separated for each element. This is to prevent a force from being applied to the protective film 18 or a change in stress of the protective film 18 when the protective film 18 is divided for each element.

Next, a predetermined region of the protective film 18 is dry-etched to form holes 24 and 25 reaching the pn electrodes 17A and 17B. The p-pad electrode 20 and the n-pad electrode 21 are formed on the protective film 18, the p-pad electrode 20 is connected to the pn electrode 17A through the hole 24, and the n-pad electrode 21 is connected to the pn electrode 17B through the hole 25. The patterns of the p-pad electrode 20 and the n-pad electrode 21 are as shown in FIG. 2. The p-pad electrode 20 and the n-pad electrode 21 are formed by vapor deposition or sputtering, and patterned by lift-off.

Next, the back surface of the substrate 10 is polished to make the substrate 10a have a predetermined thickness, and then the antireflection film 22 is formed on the back surface of the substrate 10. Then, the substrate 10 is divided into individual elements. Thus, the light emitting element according to the embodiment shown in FIG. 1 is manufactured.

### 3. EXPERIMENTAL RESULTS

Various experimental results according to the embodiment will be described.

### Experimental Example 1

After forming Ni/Au on a sapphire substrate and performing heat treatment, an Al layer was formed on the Au layer, and the reflectance was measured by emitting ultraviolet rays with a wavelength of 275 nm from a side of the sapphire substrate. Further, for comparison, the reflectance was similarly measured in the case of only Ni/Au.

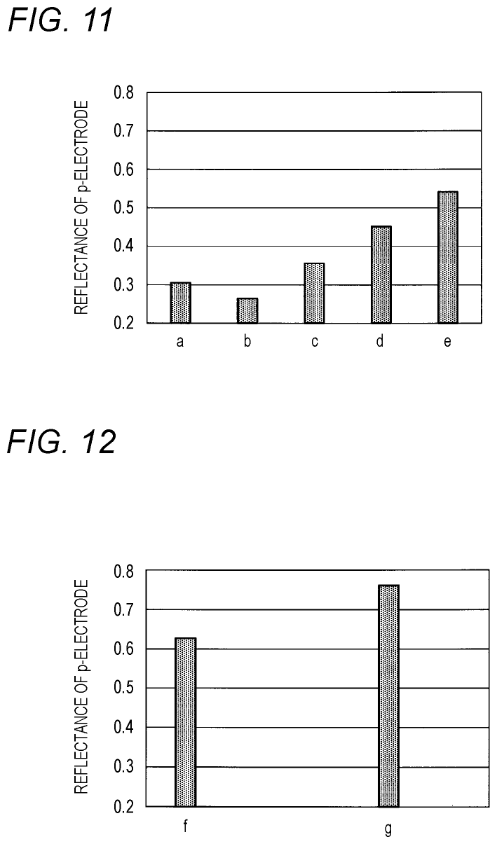

FIG. 11 is a graph showing the reflectance of samples a to e. The samples a to e differ in the thickness of Ni/Au and in the presence or absence of an Al layer. The thicknesses of the Ni/Au layer and the Al layer in each sample a to e are shown in Table 1 below. In Table 1, in the column of Ni/Au, in addition to an overall thickness, the thicknesses of the Ni layer and the Au layer are listed in parentheses.

TABLE 1

| Thickness (nm) | a | b | c | d | e |
|---|---|---|---|---|---|
| Ni/Au | 60 (10/50) | 10 (5/5) | 6 (3/3) | 4 (2/2) | 2 (1/1) |
| Al | 0 | 150 | 150 | 150 | 150 |

As shown in FIG. 11, in the Ni/Au/Al structure, it was found that the thinner the Ni/Au, the better the reflectance. In particular, it has been found that when the thickness of Ni/Au is 6 nm or less, the reflectance can be improved more than when using a structure of only Ni/Au, and the reflectance can be increased to 35% or more. Therefore, it has been found that by setting the thickness of Ni/Au to 6 nm or less in the Ni/Au/Al structure, it is possible to improve the ultraviolet reflectance while enabling ohmic contact with the p layer 14.

### Experimental Example 2

After forming an Rh layer on a sapphire substrate and performing heat treatment, an Al layer was formed, and the reflectance was measured in the same manner as in Experimental Example 1. Further, for comparison, the reflectance was similarly measured in the case where only Rh was used.

FIG. 12 is a graph showing the reflectance of each sample f and g. Sample f has a Rh single layer with a thickness of 150 nm, and sample g has a Rh/Al structure with a Rh layer of 4 nm and an Al layer of 150 nm.

As shown in FIG. 12, it was found that the reflectance of Rh/Al was higher than that of the Rh single layer, and that the reflectance was increased to 70% or more. As a result, it has been found that the Rh/Al structure enables ohmic contact and improves ultraviolet reflectance.

### Experimental Example 3

After forming a Ru layer on a sapphire substrate and performing heat treatment, an Al layer was formed, and the reflectance was measured in the same manner as in Experimental Example 1. Further, for comparison, the reflectance was similarly measured in the case where only Ru was used.

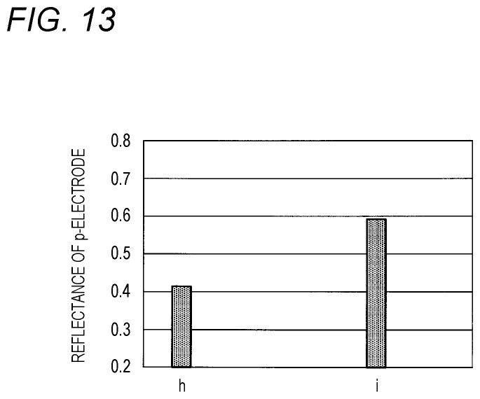

FIG. 13 is a graph showing the reflectance of each sample h and i. Sample h has a Ru single layer with a thickness of 150 nm, and sample i has a Ru/Al structure with a Ru layer of 4 nm and an Al layer of 150 nm.

As shown in FIG. 13, it was found that the reflectance of Ru/Al was higher than that of the Ru single layer, and that the reflectance was increased to 55% or more. As a result, it has been found that the Ru/Al structure enables ohmic contact and improves ultraviolet reflectance.

### REFERENCE SIGNS LIST

10: substrate
11: n layer
12: light emitting layer
13: electron block layer
14: p layer
15: p-electrode
16: n-electrode
17A, 17B: pn electrode
18: protective film
18A: first protective film
18B: second protective film
19: reflection film
20: p-pad electrode
21: n-pad electrode

What is claimed is:

1. A light emitting element comprising a group III nitride semiconductor with an emission wavelength of 200 nm or more and 280 nm or less, the light emitting element comprising:
a semiconductor layer in which an n layer, a light emitting layer, and a p layer are provided in this order; and
a p-electrode provided on and in contact with the p layer,
wherein the p-electrode comprises
a contact layer that is provided in contact with the p layer, has a thickness of 0.5 nm or more and 6 nm or less, and contains Ru or Ni/Au, and
a reflection layer that is provided in contact with the contact layer, has a thickness of 50 nm or more, and contains Al or an alloy mainly containing Al.

2. The light emitting element according to claim 1, wherein the contact layer contains Ru, a contact resistivity of the p-electrode is 3×10⁻³ Ω·cm² or less, and a reflectance at the emission wavelength is 55% or more.

3. The light emitting element according to claim 1, wherein the contact layer contains Ni/Au, a contact resistivity of the p-electrode is 2×10⁻³ Ω·cm² or less, and a reflectance at the emission wavelength is 40% or more.

4. The light emitting element according to claim 1, wherein a region where a material for the contact layer and a material for the reflection layer are mixed is not present at an interface between the contact layer and the reflection layer.

5. A manufacturing method of a light emitting element comprising a group III nitride semiconductor with an emission wavelength of 200 nm or more and 280 nm or less, the manufacturing method comprising:
forming a semiconductor layer by stacking an n layer, a light emitting layer, and a p layer in this order on a surface of a substrate;
forming a contact layer containing Rh, Ru, or Ni/Au and having a thickness of 0.5 nm or more and 6 nm or less in contact with the p layer;
performing a heat treatment to reduce a contact resistance of the contact layer to the p layer; and
forming, in contact with the contact layer, a reflection layer having a thickness of 50 nm or more and containing Al or an alloy mainly containing Al to form a p-electrode in which the contact layer and the reflection layer are stacked.

6. The manufacturing method of a light emitting element according to claim 5, wherein the contact layer contains Rh, a contact resistivity of the p-electrode is 2×10⁻² Ω·cm² or less, and a reflectance at the emission wavelength is 70% or more.

7. The manufacturing method of a light emitting element according to claim 5, wherein the contact layer contains Ru, a contact resistivity of the p-electrode is 3×10⁻³ Ω·cm² or less, and a reflectance at the emission wavelength is 55% or more.

8. The manufacturing method of a light emitting element according to claim 5, wherein the contact layer contains Ni/Au, a contact resistivity of the p-electrode is 2×10⁻³ Ω·cm² or less, and a reflectance at the emission wavelength is 40% or more.
